(19) United States
(12) Patent Application Publication
(10) Pub. No.: US 2025/0311417 A1
(43) Pub. Date: Oct. 2, 2025

(54) STACKED GATE-ALL-AROUND TRANSISTOR AND FORKSHEET TRANSISTOR

(71) Applicant: INTERNATIONAL BUSINESS MACHINES CORPORATION, ARMONK, NY (US)

(72) Inventors: Abir Shadman, Albany, NY (US); Shay Reboh, Guilderland, NY (US); Ruilong Xie, Niskayuna, NY (US); Debarghya Sarkar, Latham, NY (US)

(21) Appl. No.: 18/617,899

(22) Filed: Mar. 27, 2024

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/031; H10D 30/43; H10D 30/6735; H10D 30/6757; H10D 62/121; H10D 84/0167; H10D 84/0186; H10D 84/038; H10D 88/01

(57) ABSTRACT

A semiconductor structure, a system, and a method of forming a stacked transistor structure with a gate-all-around (GAA) transistor and a forksheet/dielectric bar. The semiconductor structure may include a set of stacked transistors. The set of stacked transistors may include a first transistor, where the first transistor includes a first gate having a gate-all-around (GAA) structure. The set of stacked transistors may also include a second transistor, where the second transistor has a gate structure different than a GAA structure. The set of stacked transistors may also include a dielectric bar. The system may include a semiconductor structure. The method may include forming a set of stacked nanosheets. The method may also include forming a dielectric bar. The method may also include selectively recessing the second layer of the dielectric bar. The method may also include depositing a first gate. The method may also include depositing a second gate.

### BACKGROUND

The present disclosure relates to semiconductors and transistors and, more specifically, to stacked field-effect transistors (FETs). Semiconductors, such as complementary metal-oxide-semiconductors (CMOS), are commonly used in computer chips and computer technology. These semiconductor chips/devices typically include transistor(s). Transistors are devices which may be used to switch or amplify electric current or voltage.

FETs use an electric field effect to control current flow within a semiconductor. FETs have three terminals-a source, a drain, and a gate. The source introduces/provides current to the transistor, the drain is the terminal that provides the output current, and the gate is used to control the current flow from the source to the drain. Specifically, FETs use the electric charge of their gates to affect and control the current flow through the channel.

Current flows using charge carriers that are either electrons or holes. Electron charge carriers are negatively charged particles (i.e., electrons) that carry charge and create an electric current. Hole charge carriers (referred to herein as holes) are positions on the FET channel that lack an electron (for instance, at positions of positive charge that is equal in magnitude to the negative charge of an electron and/or positions where an electron could or should be). These holes are positive charges, and they move in an opposite direction of electrons, in some instances. The electric charge and/or voltage of the FET gates is used to control the movements of the electrons and/or holes, which can then affect the current and charge being transmitted through the channel from the source to the drain.

One common type of FET is a nanosheet FET. Nanosheet FETs may have multiple nanosheets stacked (for example, vertically and/or horizontally) above/below each other. The nanosheets act as channels in the FET. In some instances, at least a portion of one or more sides of the nanosheet channels are surrounded by a gate material in nanosheet FETs.

### SUMMARY

The present disclosure provides a semiconductor structure, a system, and a method of forming a stacked transistor structure with a gate-all-around (GAA) transistor and a forksheet/dielectric bar. The semiconductor structure may include a set of stacked transistors. The set of stacked transistors may include a first transistor, where the first transistor includes a first gate having a gate-all-around (GAA) structure. The set of stacked transistors may also include a second transistor, where the second transistor has a gate structure different than a GAA structure. The set of stacked transistors may also include a dielectric bar.

The system may include a semiconductor structure. The semiconductor structure may include a set of stacked transistors. The set of stacked transistors may include a first transistor, where the first transistor includes a first one or more channels and a first gate having a gate-all-around (GAA) structure. The set of stacked transistors may also include a second transistor, where the second transistor includes a second one or more channels and a second gate, the second transistor having a gate structure different than a GAA structure. The set of stacked transistors may also include a dielectric bar.

The method may include forming a set of stacked nanosheets, the set of stacked nanosheets including top nanosheets and bottom nanosheets. The method may also include forming a dielectric bar, the dielectric bar including a first layer and a second layer, where the second layer is directly contacting the set of stacked nanosheets. The method may also include selectively recessing the second layer of the dielectric bar, resulting in a space between the top nanosheets and the dielectric bar. The method may also include depositing a first gate. The method may also include depositing a second gate, where the second gate surrounds all sides of the top nanosheets, resulting in a gate-all-around (GAA) structure for the second gate.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a cross-sectional view of a semiconductor structure with stacked transistors and a dielectric bar, according to some embodiments.

FIG. 2 depicts a cross-sectional view of a first intermediate stage of forming a semiconductor structure, according to some embodiments.

FIG. 3 depicts a cross-sectional view of a second intermediate stage of forming a semiconductor structure, according to some embodiments.

FIG. 4 depicts a cross-sectional view of a third intermediate stage of forming a semiconductor structure, according to some embodiments.

FIG. 5 depicts a cross-sectional view of a fourth intermediate stage of forming a semiconductor structure, according to some embodiments.

FIG. 6 depicts a cross-sectional view of a fifth intermediate stage of forming a semiconductor structure, according to some embodiments.

FIG. 7 depicts a cross-sectional view of a sixth intermediate stage of forming a semiconductor structure, according to some embodiments.

FIG. 8 depicts a cross-sectional view of a seventh intermediate stage of forming a semiconductor structure, according to some embodiments.

FIG. 9 depicts a cross-sectional view of an eighth intermediate stage of forming a semiconductor structure, according to some embodiments.

FIG. 10 depicts a cross-sectional view of a ninth intermediate stage of forming a semiconductor structure, according to some embodiments.

FIG. 11 depicts a cross-sectional view of a tenth intermediate stage of forming a semiconductor structure, according to some embodiments.

FIG. 12 depicts a cross-sectional view of an eleventh intermediate stage of forming a semiconductor structure, according to some embodiments.

FIG. 13 depicts a cross-sectional view of a twelfth intermediate stage of forming a semiconductor structure, according to some embodiments.

FIG. 14 depicts a cross-sectional view of a first example semiconductor structure, according to some embodiments.

FIG. 15 depicts a cross-sectional view of a second example semiconductor structure, according to some embodiments.

FIG. 16 depicts a cross-sectional view of a third example semiconductor structure, according to some embodiments.

FIG. 17 depicts a flowchart of an example method of forming a semiconductor structure, according to some embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to semiconductors and transistors and, more specifically, to stacked field-effect transistors (stacked FETs, also referred to as SFETs) with forksheets/dielectric bars and gate-all-around (GAA) transistors. While the present disclosure is not necessarily limited to such applications, various aspects of the disclosure may be appreciated through a discussion of various examples using this context.

Transistors, such as field-effect transistors (FETs), may be used within a system (for example, within a semiconductor structure) to switch or amplify electric current or voltage. FETs may have two typical configurations, N-channel FETs and P-channel FETs. N-channel FETs introduce (for example, through doping) an n-type impurity to the semiconductor material of the channel between the source and the drain, and P-channel FETs introduce a p-type impurity to the semiconductor material of the channel.

For n-type impurities, arsenic, phosphorous, or any other n-type material may be added to the silicon. N-type materials may have five electrons in their outer orbitals. When the n-type materials are combined with the silicon of the semiconductor, the fifth electron may not have anything to bond to and may freely move around, which may allow an electric current to flow through the silicon semiconductor channel. Because there are extra electrons from the n-type materials, the majority carriers/charge carriers for N-channel FETs are electrons.

In P-channel FETs, p-type impurities such as boron, gallium, etc., may be added to the silicon semiconductor(s) for the silicon doping. The p-type materials may have three electrons in their outer orbitals which, when added to silicon, may form holes (i.e., may lack electrons) in the valence bonds of the silicon atoms. Because there are holes in the valence bonds due to the p-type materials, the majority carriers/charge carriers for P-channel FETs are holes. An N-channel FET may be referred to herein as an NFET and a P-channel FET may be referred to herein as a PFET.

In some instances, it may be beneficial to have multiple FETs connected to each other. For example, in logic gate designs, an N-gate from an NFET may be electrically connected to a P-gate from a PFET in order to form an input for the logic gate. A logic gate may be a circuit with one or more inputs (for example, any number of inputs), but only one output. In some instances, for example, combining NFET and PFET in a logic gate design can eliminate large current leakage from VDD (a positive supply voltage) to ground in a static/non-switching period, as one of the transistors will be off which may prevent different shorts between VDD and ground. This design is conventionally referred to as a complementary metal-oxide-semiconductor (CMOS) logic design. Because of the benefits of combining NFET and PFET in a logic gate design, various logic designs may include NFET-PFET pairs.

As technology has advanced, it has become increasingly beneficial to have large amounts of technology and components in very small spaces. Reducing the size of the technology and components may be referred to herein as scaling. One method of scaling to help fit components in a small area, without reducing the capabilities of the components, is to stack transistors. Stacking transistors may increase the height of the semiconductor chip/semiconductor structure, but may reduce the area on the chip taken up by transistors. This may help allow for more components on the surface of a chip and/or may allow for a smaller chip, in some instances. For example, for logic gate designs, the connected NFET and PFET may be stacked on top of each other in order to have the benefit of the NFET-PFET pair (discussed above) while also saving space and reducing the area on the chip taken up by the NFET and PFET.

However, in conventional stacked FETs, it may be necessary and/or useful to have separation between various components of the transistors (for example, the contacts, interconnects, PFETs, NFETs, etc.) to prevent unwanted current and/or heat transfer between components. This may make it difficult for scaling and reducing the size of semiconductors/devices. For example, there may be a necessary physical separation/distance needed between an NFET and a PFET in order to help prevent unwanted current and/or heat transfer between the NFET and PFET, device shorts, etc.

In some instances, forksheets (i.e., isolation bars), also referred to herein as dielectric bars, may help create electrical and/or current separation between various components (for example, contacts, interconnects, PFETs, NFETs, etc.) of a semiconductor and/or device while also reducing the physical distance/space needed between components. A forksheet/dielectric bar may help prevent current and/or heat transfer between components (such as the NFET and PFET) due to the material(s) of the dielectric bar. In addition, a dielectric bar may allow the various components to be closer in physical location (i.e., less physically separated), as the dielectric bar is separating/isolating the components, as opposed to using physical space to separate/isolate components.

However, when a device/semiconductor has dielectric bar(s), the transistors may conventionally have a tri-gate structure, as the stacked nanosheets are connected to the dielectric bar and only three sides of the nanosheets are exposed to the gate. A tri-gate structure is a transistor structure with gate(s) on/around three sides of the channel(s). Therefore, while a dielectric bar may improve scaling and reduce the space/distance between transistors, a dielectric bar may also reduce the amount of gates, as one sidewall of stacked nanosheets may be directly connected to and/or contacting the dielectric bar (instead of to the gate(s)). Only having a tri-gate structure (as opposed to a gate-all-around (GAA) structure) due to the forksheet may have a negative impact on PFETs in particular, as a tri-gate nanosheet transistor structure may have limited hole mobility, for instances, due to the elimination of one sidewall (for example, on the (110) surface) of the channel in (001)-Si orientation.

Additionally, conventional stacked transistor structures, such as those that include dielectric bar(s), may not allow for flexibility and/or variability in the structure (for example, the gate structure) for the top transistor and the bottom transistor. Put differently, conventional stacked transistor structures, and the methods for forming conventional stacked transistor structures, may not allow for different gate structures (such as dual work function metal (WFM) schemes) for the top transistor and the bottom transistor. This may be because conventional stacked transistors have a continuous path (e.g., a merged gate cavity) between the top and bottom transistors and the corresponding top and bottom gates. This may render it extremely difficult to change/remove/replace WFM operations for one FET without penalizing the other FET in the set of stacked transistors.

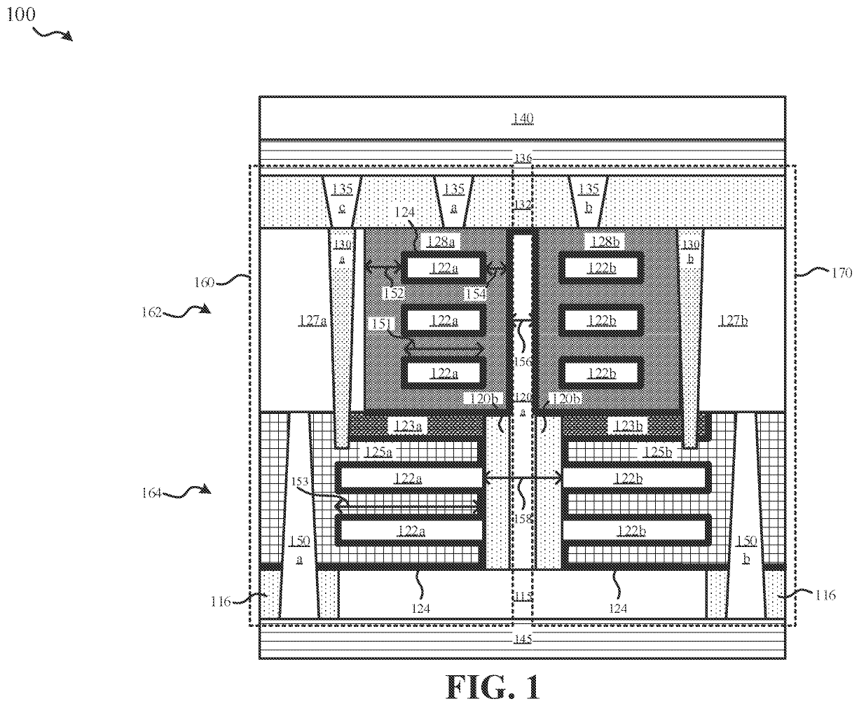

Below, above, on top of, etc. may refer to components (such as transistors) and their positions when looking at a cross-sectional view such as the views depicted in FIGS. 1-16.

However, it is advantageous to have different gate structures for the top and bottom transistors. For instance, an NFET has electron charge carriers and a PFET has hole charge carriers, and different gate structures may have different impacts on electron mobility compared to hole mobility. The ability to have different gate structures for the different transistors (e.g., a top transistor and a bottom transistor) may allow for gate structures that can be tailored specifically for electron mobility and/or hole mobility, which may improve the functioning of the stacked transistors.

The present disclosure relates to semiconductors and transistors and, more specifically, to stacked FETs with dielectric bars. As discussed herein, dielectric bars can help improve scaling and decrease the size of the semiconductors and transistors, particularly the portions of the components (such as the base(s) of the components) attached to the substrate and/or chip, as dielectric bars may allow for components to be in closer proximity to each other due to the isolation created by the dielectric bars. Therefore, dielectric bar(s) may be desired to help decrease the size of a device and/or semiconductor chip and its components.

However, in conventional nanosheet transistors, the addition of a dielectric bar may cause the nanosheet transistor to have a tri-gate structure with only three sides of the nanosheets exposed to the gate material, which may negatively impact PFET structures, in particular, and PFET hole mobility. Electron mobility and NFET structures may not be negatively impacted by a tri-gate structure.

To help reduce and/or eliminate any issues, particularly in the PFET region of the stacked transistors, due to a dielectric bar, while also allowing for additional scaling by utilizing the dielectric bar, stacked FETs with dielectric bars and different gate structures are discussed herein. Different gate structures in the different transistors within a stacked FET set may also be referred to herein as different and/or dual WFM structures.

By utilizing different gate structures, the NFET portion of the stacked transistor set may include a gate structure, or WFM structure, that is beneficial for scaling as well as the functionality of the NFET, as electron charge carriers are not negatively affected by a tri-gate structure (as opposed to a gate-all-around (GAA) structure). However, the PFET portion of the stacked transistor set, which is negatively affected by a tri-gate structure, may instead have a different gate/WFM structure that is a gate-all-around (GAA structure). A GAA structure may surround the channels/nanosheets on all four sides (for example, when viewing from the cross-sections depicted in FIGS. 1-16) which may help increase current flow (also referred to as drive current) as well as decrease current leakage. By utilizing different gate structures such as a PFET GAA structure and an NFET tri-gate structure (with a dielectric bar), the stacked transistors may still have the scaling benefits due to the dielectric bar and may also eliminate/reduce any negative impacts to the PFET portion (due to the use of the dielectric bar) by utilizing a GAA structure instead of a tri-gate structure, as the GAA structure has gate(s) surrounding all four sides/sidewalls (including on the (110) surface, in some instances) of the channel (for example, in (001)-Si orientation).

According to an aspect of the invention, there is provided a semiconductor structure, where the semiconductor structure includes a set of stacked transistors, where the set of stacked transistors includes a first transistor, where the first transistor includes a gate having a gate-all-around (GAA) structure, a second transistor, where the second transistor has a gate structure different than a GAA structure, and a dielectric bar. In some instances, the use of a dielectric bar can serve to create electrical and/or current separation between components of a semiconductor and can serve to reduce physical distance/space between components (i.e., improve scaling of the semiconductor structure). In some instances, a GAA structure can serve to improve hole mobility, which is especially beneficial to PFETs, and can help improve the functioning of the semiconductor structure.

In some embodiments, the second transistor includes a gate having a tri-gate structure. In some instances, the use of a tri-gate structure can serve to improve scaling and reduce physical distance/space between components, as the gate(s) may be connected to three sides of the channel(s)/nanosheet(s), which may open up the fourth side of the channel(s) to contact with other components, such as the dielectric bar.

In some embodiments, the first transistor is in a top region of the set of stacked transistors and the second transistor is in a bottom region of the set of stacked transistors. In some embodiments, the dielectric bar has a first width in the top region of the set of stacked transistors and a second width, different from the first width, in the bottom region of the set of stacked transistors. In some embodiments, the second width is wider than the first width. In some instances, the second wider width can allow for a tri-gate structure for the second transistor, which may help improve scaling of the semiconductor structure. In some instances, the wider width of the second width can also serve to prevent unwanted gate removal during any gate recessing and/or selective recessing processes.

In some embodiments, the dielectric bar includes a first layer and a second layer. In some embodiments, the first layer is in the top region and the bottom region and the second layer is only in the bottom region. In some embodiments, the second layer includes one or more different materials than the first layer. In some instances, the multiple layers of the dielectric bar can help with customization/tailoring of the dielectric bar and can help create different gate structures (including a GAA structure) for the first and second transistor.

In some embodiments, the first transistor has a first gate extension between one or more channels and the dielectric bar and a second gate extension, different from the first gate extension, between the one or more channels and a gate cut pillar. In some embodiments, the first gate extension is smaller than the second gate extension. In some instances, the smaller gate extension of the first gate extension can help with the formation/inclusion of a GAA structure, while also preventing too much gate extension in order to help with scaling of the semiconductor structure.

In some embodiments, the one or more channels are nanosheets. In some instances, nanosheet transistors and nanosheet channels may help with scaling and decreasing size of a semiconductor structure, as a plurality of nanosheets may be stacked on top of each other, resulting in multiple channels without taking up too much space on a surface of a semiconductor structure/chip.

According to an aspect of the invention, there is provided a system, where the system comprises a semiconductor structure, where the semiconductor structure includes a set of stacked transistors, where the set of stacked transistors includes a first transistor, where the first transistor includes a first one or more channels and a first gate having a gate-all-around (GAA) structure, a second transistor, where the second transistor includes a second one or more channels and a second gate, the second transistor having a gate structure different than a GAA structure, and a dielectric bar. In some instances, the use of a dielectric bar can serve to create electrical and/or current separation between components of a semiconductor and can serve to reduce physical distance/space between components (i.e., improve scaling of the semiconductor structure). In some instances, a GAA structure can serve to improve hole mobility, which is especially beneficial to PFETs, and can help improve the functioning of the semiconductor structure.

In some embodiments, the second gate has a tri-gate structure. In some instances, the use of a tri-gate structure can serve to improve scaling and reduce physical distance/space between components, as the gate(s) may be connected to three sides of the channel(s)/nanosheet(s), which may open up the fourth side of the channel(s) to contact with other components, such as the dielectric bar.

In some embodiments, the first one or more channels have a first width and the second one or more channels have a second width different than the first width. In some embodiments, the second width is greater than the first width. In some instances, a second width greater than the first width can help prevent short channel effects for the second one or more channels, due to the wider width, as the first one or more channels may already be protected from at least some short channel effects due to the GAA structure.

In some embodiments, the system further includes a contact via connected to the first gate and the second gate, and a contact connected to the first gate and an interconnect, where the second gate is connected to the interconnect through the contact via and the first gate. In some instances, the contact via can serve to help form a shared gate structure for the first gate and the second gate.

In some embodiments, the system further includes a contact via connected to the second gate, where the contact via is separated from the first gate, a first contact connected to the contact via and an interconnect, where the second gate is connected to the interconnect through the contact via and the first contact, and a second contact connected to the first gate and the interconnect. In some instances, the contact via can serve to help form an independent gate structure for the first gate and the second gate.

In some embodiments, the dielectric bar has a first width in a top region of the set of stacked transistors and a second width, different from the first width, in a bottom region of the set of stacked transistors. In some embodiments, the second width is wider than the first width. In some instances, the second wider width can allow for a tri-gate structure for the second transistor, which may help improve scaling of the semiconductor structure. In some instances, the wider width of the second width can also serve to prevent unwanted gate removal during any gate recessing and/or selective recessing processes.

According to an aspect of the invention, there is provided a method of forming a semiconductor structure, the method including forming a set of stacked nanosheets, the set of stacked nanosheets including top nanosheets and bottom nanosheets; forming a dielectric bar, the dielectric bar including a first layer and a second layer, where the second layer is directly contacting the set of stacked nanosheets; selectively recessing the second layer of the dielectric bar, resulting in a space between the top nanosheets and the dielectric bar; depositing a first gate; and depositing a second gate, where the second gate surrounds all sides of the top nanosheets, resulting in a gate-all-around (GAA) structure for the second gate. In some instances, the use of a dielectric bar can serve to create electrical and/or current separation between components of a semiconductor and can serve to reduce physical distance/space between components (i.e., improve scaling of the semiconductor structure). In some instances, a GAA structure can serve to improve hole mobility, which is especially beneficial to PFETs, and can help improve the functioning of the semiconductor structure.

Referring now to FIG. 1, a cross-sectional view of a semiconductor structure 100 with stacked transistors and a dielectric bar is depicted, according to some embodiments. The cross-sectional views depicted in FIGS. 1-16 are cross-section(s) in a gate region (for example, a cross-section along the PC and/or the gate) of a semiconductor structure.

Semiconductor structure 100 includes a backside interconnect 145 with backside contacts 150a and 150b (referred to collectively as backside contacts 150) directly connected to the backside interconnect 145, as well as a frontside interconnect 136 with frontside contacts 135a, 135b, and 135c (referred to collectively as frontside contacts 135) directly connected to the frontside interconnect 136. In some instances, backside interconnect 145 and frontside interconnect 136 may be back end of line (BEOL) interconnects. Frontside and backside, as referred to herein, may refer to the frontside and backside of a semiconductor die/chip. In some instances, contacts 150 and 135 may be metal contacts, and may be a metal material such as cobalt (Co), tungsten (W), copper (Cu), ruthenium (Ru), etc. In some instances, as depicted in FIG. 1, backside contacts 150 may have direct contact with dielectric 116, gate(s) 125, and gate cut pillar(s) 127a and/or b (referred to collectively as gate cut pillar(s) 127).

Frontside contacts 135 may be directly and/or indirectly connected to contact vias 130a and 130b (collectively contact vias 130). Contact vias 130 connect the bottom gates 125 to the frontside contacts 135 (specifically, frontside contacts 135c and 135b) and the frontside interconnect 136. In some instances, as depicted in FIG. 1, the contact vias 130 extend through the MDI 123 and touch/have direct contact with the bottom gate(s) 125. In some instances, contact vias 130 may be metal contacts, and may be a metal material such as Co, W, Cu, Ru, etc. FIG. 1 depicts two exemplary types of gate connections, independent gates/connections and dependent gates/connections. Specifically, FIG. 1 depicts an example of independent gates for stacked transistors 160, and shared gates for stacked transistors 170.

Specifically, for stacked transistors 160, contact via 130a is directly connected to bottom gate 125a and to contact 135c, creating a connection between bottom gate 125a and frontside interconnect 136. However, contact via 130a has no direct connection to top gate 128a, and instead contact via 130a is separated from top gate 128a by gate cut pillar 127a (also referred to as CT pillar 127a). Because contact via 130a has no direct connection to top gate 128a, top gate 128a and bottom gate 125a are not connected through contact via 130a, and are independent gates. Top gate 128a is connected to frontside interconnect 136 through frontside contact 135a.

For stacked transistors 170, contact via 130b is directly connected to both top gate 128b and bottom gate 125b. Therefore, contact via 130b connects bottom gate 125b to top gate 128b, resulting in shared gates (125b and 128b). Top gate 128b is connected to frontside interconnect 136 through frontside contact 135b and, due to contact via 130b connecting bottom gate 125b to top gate 128b, bottom gate 125b is connected to frontside interconnect 136 through its shared gate connection to top gate 128b and the connection between top gate 128b and frontside contact 135b. This is referred to herein as a shared gate structure.

Although FIG. 1 depicts stacked transistors 160 having independent gates and stacked transistors 170 having shared gates, semiconductor structure 100 may include any combination of shared and/or independent gates. For example, stacked transistors 160 and 170 may both have shared gates, stacked transistors 160 and 170 may both have independent gates, stacked transistors 160 may have shared gates and stacked transistors 170 may have independent gates, etc.

Semiconductor structure 100 may also include a wafer 140 (for example, a handler wafer) on top of (when viewing from the cross-section depicted in FIG. 1) the frontside interconnect 136, as well as a wafer/substrate 115 on top of the backside interconnect 145. Semiconductor structure 100 further includes various dielectrics, including dielectric 116 and dielectric 132. In some instances, dielectric 116 is shallow trench isolation (STI), and may help prevent current leakage and/or heat transfer between various components of the semiconductor structure 100. In some instances, dielectric 116 and dielectric 132 may be dielectric materials such as silicon nitride (SiN), silicon dioxide (SiO₂), other oxide(s), silicoboron carbonitride (SiBCN), silicon oxycarbonitride (SiOCN), silicon carbide (SiC), silicon oxycarbide (SiOC), etc. In some instances, dielectric 116 and dielectric 132 may be the same material(s). In some instances, dielectric 116 and dielectric 132 may be different materials.

As depicted in FIG. 1, semiconductor structure 100 includes two sets of stacked transistors, stacked transistors 160 and stacked transistors 170, separated by dielectric bars 120a and 120b (referred to collectively as dielectric bar 120). Each set of stacked transistors 160 and 170 include a top transistor 162 and a bottom transistor 164. Although semiconductor structure 100 depicts four transistors (a top 162 and bottom 164 transistor for stacked transistors 160, and a top 162 and bottom 164 transistor for stacked transistors 170), semiconductor structure 100 may include any number of transistors. In some instances, each transistor includes stacked nanosheets 122a and/or 122b. FIG. 1 depicts the nanosheets that make up the set of stacked transistors 160 as nanosheets 122a and the nanosheets that make up the set of stacked transistors 170 as nanosheets 122b, however the nanosheets may also be referred to collectively as nanosheets 122. In some instances, the nanosheets 122 may include silicon (Si) (or silicon compound) materials.

In some instances, the nanosheets 122 of the top transistors 162 (also referred to as top nanosheets) may be separated from the nanosheets 122 of the bottom transistors 164 (also referred to as bottom nanosheets) by middle dielectric isolation (MDI) 123a and 123b. MDI 123a may correspond to stacked transistors 160 and MDI 123b may correspond to stacked transistors 170, and MDI 123a and 123b may be referred to collectively as MDI 123, in some instances. In some instances, MDI 123 may be dielectric materials such as SiN, SiO₂, other oxide(s), SiBCN, SiOCN, SiC, SiOC, etc.

Semiconductor structure 100 includes gates 128a and 128b (collectively gates 128) for the top transistors 162 and gates 125a and 125b (collectively gates 125) for the bottom transistors 164 in the stacked transistor sets 160 and 170. The gates 125 and 128 may surround a plurality of sides of the corresponding nanosheets 122, discussed further herein. In some instances, as depicted in FIG. 1, gates 128 (for the top transistors 162) are gate-all-around (GAA) structures, and are in direct contact with all sides of the corresponding nanosheets 122. For example, when viewing from the cross-section depicted in FIG. 1, gates 128 are in contact with all four sides of the corresponding nanosheets 122. In some instances, the top transistors 162 in the sets of stacked nanosheets 160 and 170 are PFETs. As discussed herein, a tri-gate structure can have a negative impact on PFETs in particular due to limited hole mobility. However, a GAA may not have the same negative impacts on PFETs and may instead improve hole mobility and the functioning of PFETs due to the additional contact between the gate(s) 128 and the corresponding nanosheets 122.

As discussed herein, a dielectric bar (such as dielectric bar 120) may help improve scaling and reduce the space/distance between transistors (such as stacked transistors 160 and 170). A tri-gate structure may help further improve scaling and reduce spacing/distance between transistors, as the nanosheets may be in direct contact with the dielectric bar in a tri-gate structure. In some instances, as depicted in FIG. 1, gates 125 are tri-gate structures, and are in direct contact with three sides (for example, when viewing from the cross-section depicted in FIG. 1) of the corresponding nanosheets 122. By utilizing a tri-gate structure, the corresponding nanosheets 122 (for instance, the nanosheets 122 for the bottom transistors 164) are in direct contact with the dielectric bar 120, therefore helping decrease spacing/distance between the nanosheets 122.

In some instances, as depicted in FIG. 1, dielectric bar 120 may include a first portion/layer 120a and second portion/layer(s) 120b. The first layer 120a of the dielectric bar 120 may extend along both the top 162 and bottom 164 transistors and may help separate stacked transistors 160 from stacked transistors 170 (and vice versa). Put differently, the first layer 120a of the dielectric bar 120 may be in both the PFET region (for example, the top transistor 162 region) and NFET region (for example, the bottom transistor 164 region) of the stacked transistors 160 and 170. However, as depicted in FIG. 1, the second layer(s) 120b of the dielectric bar 120 may only separate the NFETs (for example, bottom transistors 164) from each other and may only be in an NFET region of the stacked transistor structure. In some instances, layer 120a of the dielectric bar may be described as being part of both the top 162 and bottom 164 transistor portions of the semiconductor structure 100, and layers 120b may be described as being part of/in a bottom 164 transistor portion of the semiconductor structure 100. In some instances, although layer(s) 120b are depicted in FIG. 1 as being on either side of layer 120a (and, in some instances, may not be a continuous component but instead a plurality of components), layers 120b may be referred to herein as layer 120b and/or second layer 120b.

As depicted in FIG. 1, the width 158 of a bottom portion of the dielectric bar 120 (for example, the layers 120a and 120b of dielectric bar 120 in the bottom transistor 164 region of the semiconductor structure 100) is wider than the width 156 of a top portion of the dielectric bar 120 (for example, the layer 120a of dielectric bar 120 in the top transistor 162 region of the semiconductor structure 100). The wider width 158 allows for a tri-gate structure for the bottom transistors 164, which may help improve scaling of the semiconductor structure (due to the dielectric bar 120 and the tri-gate structure). Further, as the bottom transistors 164 may be NFETs, in some instances, the NFETs may not be negatively affected by the use of a tri-gate structure (as opposed to a gate-all-around (GAA) structure).

The narrower width 156 in the top transistor 162 region of the semiconductor structure 100 may allow for space 154 between the nanosheets 122 in the top transistor 162 region and the dielectric bar 120. This space 154 may allow for the inclusion of gate(s) 128 between nanosheets 122 and dielectric bar 120 for the top transistors 162, which results in a GAA structure for the top transistors 162. Transistors with a GAA structure, such as top transistors 162, may be described herein as being GAA transistors. Transistors with a tri-gate structure and nanosheets 122 directly connected to and/or directly contacting dielectric bar 120, such as bottom transistors 164, may be described herein as being dielectric bar transistors and/or forksheet transistors.

In some instances, as depicted in FIG. 1, the width/spacing 154 between the nanosheets 122 and the dielectric bar 120 (in the top transistor 162 region) is smaller than the width/spacing 152 between the nanosheets 122 and the gate cut pillars 127. These widths/spacing 152 and 154 may also be referred to herein as gate extension 152 and 154, as they are the extension(s) of the gate(s) 128 beyond the nanosheets 122. The smaller gate extension 154 between the nanosheets 122 and the dielectric bar 120 may help with the formation/inclusion of a GAA structure, while also preventing too much gate extension 154, which may be unnecessary and may not help improve scaling of the nanosheet structure. Put differently, too much gate extension 154 between the nanosheets 122 and the dielectric bar 120 may result in an unnecessarily wide width 158 of the dielectric bar 120 in the bottom transistor 164 region of the semiconductor structure 100, which may not be beneficial for scaling of the stacked transistors and the semiconductor structure 100. Gate extension 154 may be referred to herein as the gate extension 154 in the dielectric bar region, as it is the gate extension 154 between the nanosheets 122 and the dielectric bar 120. Gate extension 152 may be referred to herein as the gate extension 152 in the gate cut pillar region, as it is the gate extension 152 between the nanosheets 122 and the gate cut pillar(s) 127.

In some instances, the width 151 of the channels/nanosheets 122 of the top transistors 162 may be smaller than the width 153 of the channels/nanosheets 122 of the bottom transistors 164. These widths 151 and 153 may also be referred to herein as top channel width(s) 151 and bottom channel width(s) 153, as the nanosheets 122 are channels for the top transistors 162 and bottom transistors 164. As semiconductor structures continue to get further scaled and increasingly smaller, one negative impact that can occur is short channel effects. A GAA structure, such as gate(s) 128, can help prevent short channel effects. Therefore, the top channels/nanosheets 122 of the top transistors 162 may be less likely, or even unlikely, to face short channel effects due to the GAA structure of gates 128, and thus can have a shorter channel width 151 (i.e., top channel width 151). The greater/longer width 153 of the bottom channels/nanosheets 122 (also referred to herein as bottom channel width 153) may help prevent short channel effects in the bottom channels/nanosheets 122 and bottom transistors 164, even with the tri-gate structure of gates 125.

In some instances, dielectric bar 120 and portions/layers 120a and 120b may be dielectric material(s). For example, portions/layers 120a and/or 120b of the dielectric bar 120 may be dielectric material(s) such as SIN, SiO₂, SiBCN, SiOCN, SiC, SiOC, other oxides, etc. In some instances, layers 120a and 120b are the same dielectric material(s). In some instances, layers 120a and 120b are different dielectric material(s).

In some instances, gates 125 and/or 128 may be metal gates and may contain metal material(s). In some instances, gates 125 and/or 128 may contain a layer of gate insulator, such as HfO₂, HfSiOx, HfLaOx, HfAlOx, etc., and metal gate material(s), including work function metals, such as TIN, TiAlC, TiC, etc., and conductive metals such as W, Co, tantalum (Ta), titanium (Ti), niobium (Nb), ruthenium (Ru), etc., and/or compounds containing these metal material(s).

In some instances, an inter-layer (IL) high-k (HK) dielectric 124 (referred to herein as IL/HK dielectric 124) may be layered between various components of the semiconductor structure 100. For example, in some instances, as depicted in FIG. 1, IL/HK dielectric 124 may surround a plurality of sides of each nanosheet 122. In some instances, the IL/HK dielectric 124 may be in channel (nanosheet 122) and/or gate (125 and/or 128) regions of the semiconductor structure 100. For example, the IL/HK dielectric 124 may act as a gate dielectric and induce charges in the channels (nanosheets 122) through a capacitive effect, which may help improve the performance of the stacked transistors 160, 170. IL/HK dielectric 124 may be high-k dielectric material(s) such as Si, SiO₂, etc. In other instances (not depicted), semiconductor structure 100 may not include IL/HK dielectric 124.

In some instances, components of the semiconductor structure 100 may be described as directly connected to, connected to, contacting, surrounding, etc. other components of the semiconductor structure 100, even with the existence of IL/HK dielectric 124 between the components, as the IL/HK dielectric 124 may enhance the performance of the components and may not sever the connection between the components. Put differently, components of the semiconductor structure 100 may be described as directly connected to, connected to, surrounding, etc. even if there is an IL/HK dielectric, such as IL/HK dielectric 124, between them. For example, gates 128 may be described as surrounding nanosheets 122, even though there may be a layer of IL/HK dielectric 124 between the nanosheets 122 and the gates 128. In another example, dielectric bar 120 may be described as connected to and/or directly connected to gates 125 and/or 128, even though there may be a layer of IL/HK dielectric 124 between the dielectric bar 120 and the gates 125 and/or 128.

FIG. 1 depicts two nanosheets 122 in each bottom transistor 164 and three nanosheets 122 in each top transistor 162. Although specific numbers of nanosheets 122 are depicted in each transistor, these numbers of nanosheets 122 are meant to be exemplary and not limiting. For example, in some instances, semiconductor structure 100 may include 1-5 channels/nanosheets 122 in each transistor in the semiconductor structure 100. Put differently, the bottom transistors 164 may include 1 to 5 channels/nanosheets 122 in each transistor and top transistors 162 may include 1 to 5 channels/nanosheets 122 in each transistor.

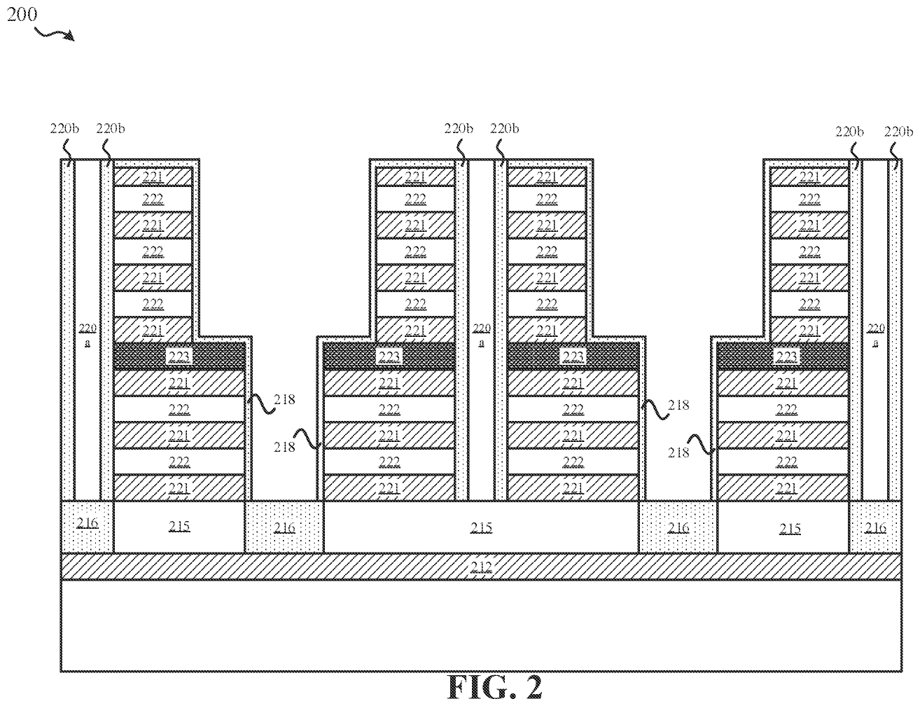

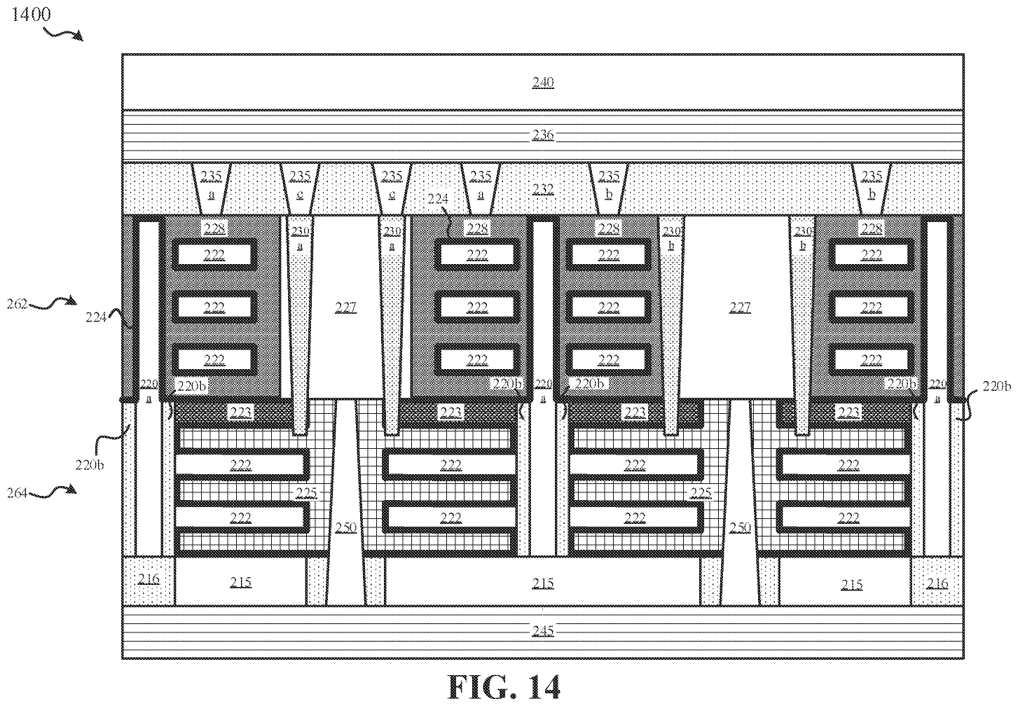

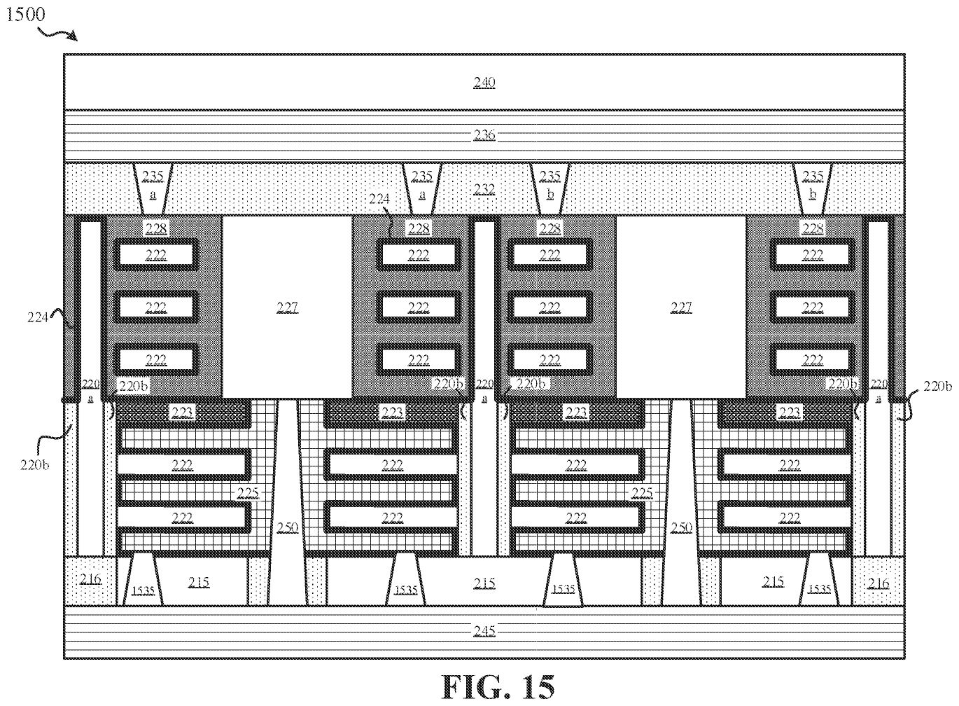

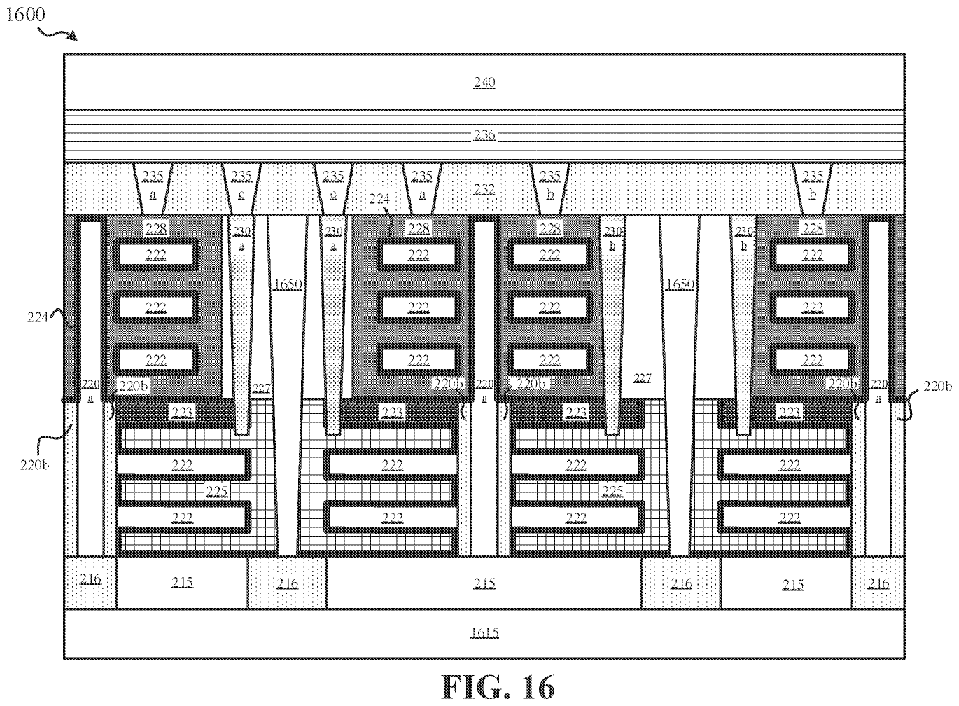

Referring now to FIGS. 2-13, FIGS. 2-13 depict intermediate stages in the process of forming semiconductor structure 1400 (FIG. 14), according to some embodiments. Further, although FIGS. 2-13 and intermediate stages 200-1300 are described herein as forming semiconductor structure 1400 (FIG. 14), the same/similar steps may be used to form semiconductor structure 100 (FIG. 1), semiconductor structure 1500 (FIG. 15), and/or semiconductor structure 1600 (FIG. 16). FIGS. 2-16 are depicted from a cross-sectional view in a gate region of the semiconductor structure(s).

Referring now to FIG. 2, a cross-sectional view of an intermediate stage 200 of forming a semiconductor structure is depicted, according to some embodiments. Intermediate stage 200 includes a substrate 210, an etch stop layer 212, and a wafer/substrate 215. In some instances, substrate(s) 210 and/or 215 may be silicon (Si) substrate(s). In some instances, etch stop layer 212 may be SiGe. Intermediate stage 200 may also include dielectric 216 (for example, shallow trench isolation (STI)). Dielectric 216 may be dielectric material(s) such as SiN, SiO₂, other oxide(s), SiBCN, SiOCN, SiC, SiOC, etc.

As depicted in FIG. 2, intermediate stage 200 includes nanosheets 222 (e.g., Si and/or Si compounds), sacrificial sheets 221 (e.g., SiGe), and MDI 223 (e.g., SiN, SiO₂, other oxide(s), SiBCN, SiOCN, SiC, SiOC, etc.). The nanosheets 222 may be separated by at least a sacrificial sheet 221 and, in some instances, may be separated by both MDI 223 and sacrificial sheets 221. In some instances, the width (for example, when viewing from the cross-section depicted in FIG. 2) of the nanosheets 222 below the MDI 223 may be greater/wider than the width of the nanosheets 222 above the MDI 223. The nanosheets 222 below the MDI 223 may correspond to bottom transistor(s) nanosheets and the nanosheets 222 above the MDI 223 may correspond to top transistor(s) nanosheets, therefore the nanosheets 222 for the top transistors may have a smaller width than the nanosheets 222 for the bottom transistors (discussed further herein in relation to FIG. 1). In some instances, the nanosheets 222 corresponding to the bottom transistor(s) may be referred to herein as bottom nanosheets and the nanosheets 222 corresponding to the top transistor(s) may be referred to herein as top nanosheets.

In some instances, as depicted in FIG. 2, there is a thin layer of dielectric 218 (e.g., SiN, SiO₂, other oxide(s), SiBCN, SiOCN, SiC, SiOC, etc.) connected to any exposed edges (i.e., edges not connected to other components of intermediate stage 200) of the nanosheets 222, MDI 223, and sacrificial sheets 221. Dielectric 218 may help protect the nanosheets 222, MDI 223, and sacrificial sheets 221 from any unwanted etching.

Intermediate stage 200 includes a dielectric bar 220 (including portions/layers 220a and 220b). In some instances, layers 220a and 220b may be dielectric material(s) such as SiN, SiO₂, SiBCN, SiOCN, SiC, SiOC, other oxides, etc. In some instances, layers 220a and 220b are the same dielectric material(s). In some instances, layers 220a and 220b are different dielectric material(s). In some instances, as depicted in FIG. 2, layer(s) 220b of the dielectric bar(s) 220 may be directly connected to and/or contacting the nanosheets 222 in intermediate stage 200.

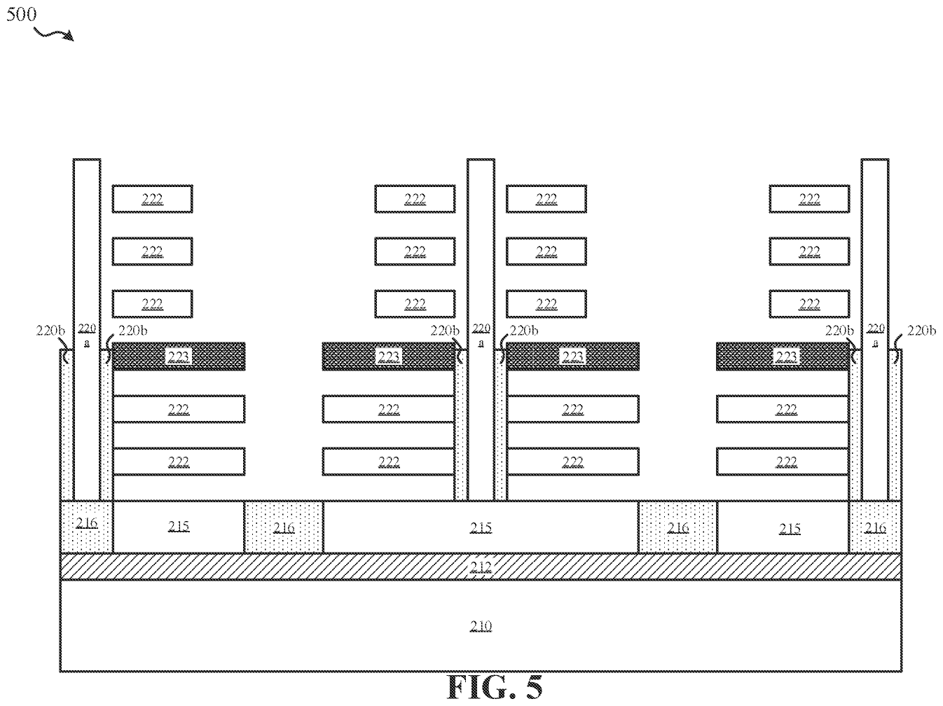

Although layers 220a and 220b of the dielectric bar (referred to collectively as dielectric bar 220) are depicted as separate entities in FIG. 2 (for instance, due to the possibility of different materials as well as for clarity in future intermediate stages (e.g., intermediate stage 500 (FIG. 5))) layers 220a and 220b may together make up the dielectric bar 220 and may not be separate entities.

In some instances, as discussed further herein, dielectric bars 220 may help create electrical and/or current separation between various components and may help with scaling (i.e., reducing the physical distance/space between components). For instance, in intermediate structure 200, dielectric bar(s) may help bring the various nanosheets 222 and transistors closer together, thus reducing the space between components.

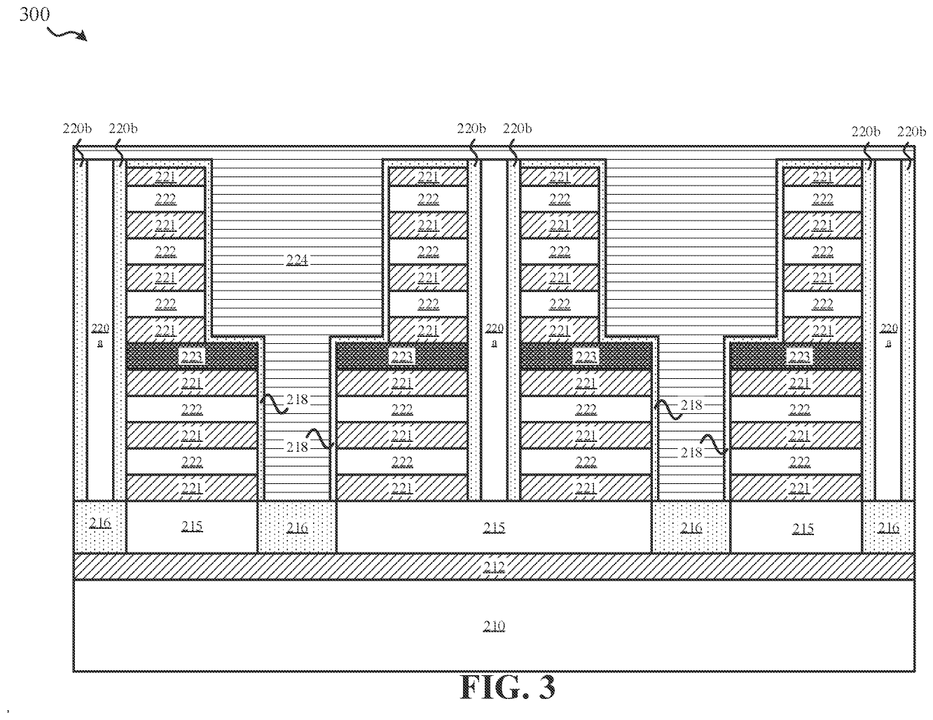

Referring to FIG. 3, a cross-sectional view of an intermediate stage 300 of forming a semiconductor structure is depicted, according to some embodiments. In intermediate stage 300, dummy gate 224 is deposited (also referred to herein as a dummy gate 224 fill). In some instances, dummy gate 224 is deposited/filled through methods such as atomic layer deposition (ALD), chemical vapor deposition (CVD), laser induced chemical vapor deposition (LCVD), and/or any other deposition technique. Dummy gate 224 may serve as a placeholder for a gate structure during the formation process of a semiconductor structure.

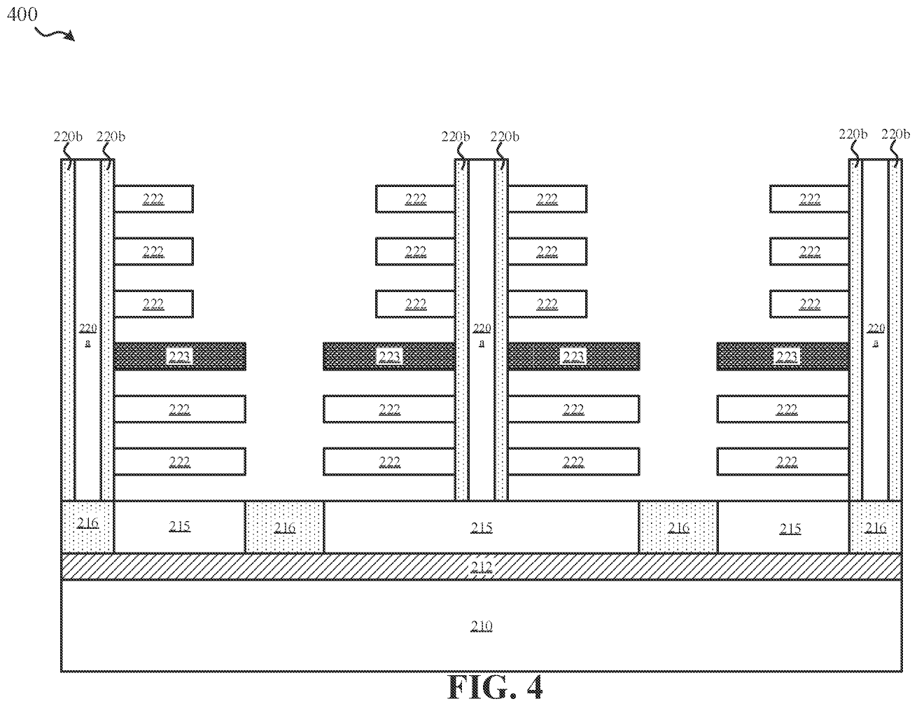

Referring to FIG. 4, a cross-sectional view of an intermediate stage 400 of forming a semiconductor structure is depicted, according to some embodiments. Intermediate stage 400 may include a dummy gate 224 pull (i.e., a pull/removal of dummy gate 224) as well as a channel release to remove the sacrificial sheets 221 and release/expose the channels (i.e., nanosheets 222). In some instances, the dummy gate 224 pull may include removal/etching using a selective wet etch or dry etch process.

In some instances, as discussed herein, sacrificial sheets 221 may be SiGe. This way, sacrificial sheets 221 may be removed without removing any other materials/components of the semiconductor structure, as the removal process(es) can be tailored to the SiGe (and even to a specific germanium content, in some instances). Put differently, the channel release/removal of the sacrificial sheets 221 may utilize etch selectivity, where the etchant used may have a high selectivity to sacrificial sheets 221 (e.g., SiGe). This way, the sacrificial sheets 221 are removed while preventing any unwanted removal of other components of the intermediate structure.

Referring to FIG. 5, a cross-sectional view of an intermediate stage 500 of forming a semiconductor structure is depicted, according to some embodiments. Intermediate stage 500 may include selectively recessing the dielectric bar 220, specifically layer 220b of the dielectric bar 220. As discussed herein, it may be beneficial to have stacked transistors with different gate structures for the top and bottom transistors. Specifically, it may be beneficial to have a GAA structure, or a GAA transistor, for the PFET to help with hole mobility. To achieve a GAA structure for the PFET, a portion/layer 220b of the dielectric bar 220 may be selectively recessed in order to create space between the PFET nanosheets 222 (in this instance, the top nanosheets 222) and the dielectric bar 220. For example, layer 220b of the dielectric bar 220 may be an oxide material, in some instances, and a wet etch process/solution may be used to selectively etch the oxide material without etching/removing any of layer 220a of the dielectric bar. In some instances, layer 220b may be selectively recessed to a middle of MDI 223 (i.e., below a top (when viewing from the cross-section depicted in FIG. 5) of MDI 223. Techniques such as RIE and/or other etching techniques that achieve a selectivity with the ability to partially recess layer 220b (for example, without etching too much of the layer 220b).

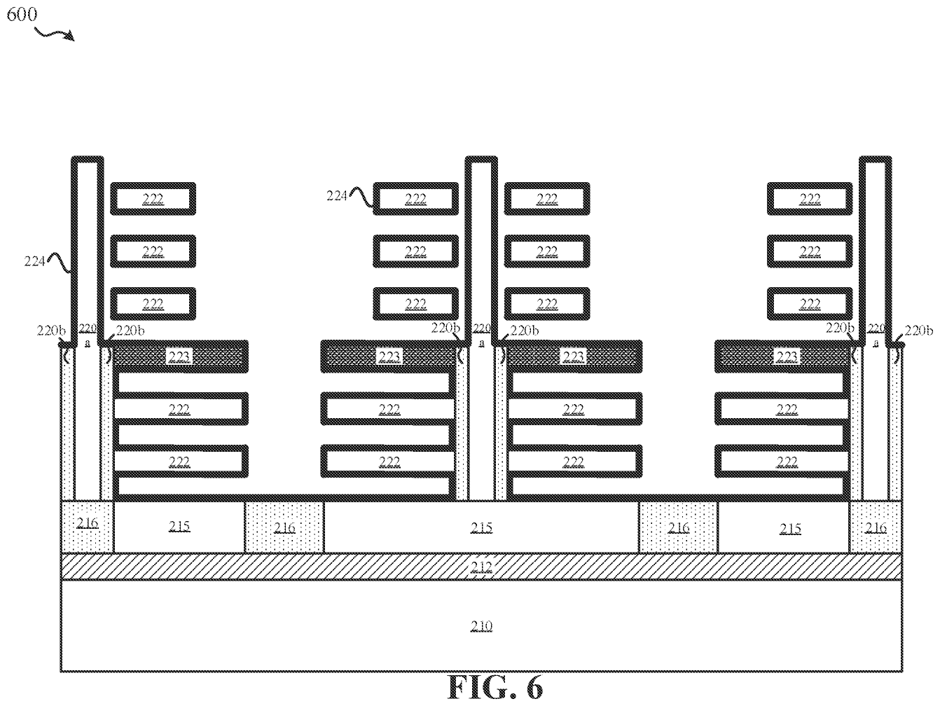

Referring to FIG. 6, a cross-sectional view of an intermediate stage 600 of forming a semiconductor structure is depicted, according to some embodiments. Intermediate stage 600 may include depositing an inter-layer (IL)/high-k (HK) dielectric 224 around exposed areas of various components of intermediate stage 600. For example, IL/HK dielectric 224 may be deposited surrounding all sides of the nanosheets 222 above MDI 223 (i.e., the nanosheets 222 corresponding to the top transistors) and surrounding three sides of the nanosheets 222 below MDI 223 (i.e., the nanosheets 222 corresponding to the bottom transistors). IL/HK dielectric 224 may also be deposited along portions of the dielectric bars 220 and other components of intermediate stage 600. In some instances, IL/HK dielectric 224 is deposited/filled through methods such as atomic layer deposition (ALD), chemical vapor deposition (CVD), laser induced chemical vapor deposition (LCVD), and/or any other deposition technique. As discussed herein, IL/HK dielectric 224 may act as a gate dielectric and induce charges in the channels (nanosheets 222) through a capacitive effect, which may help improve the performance of the stacked transistors and the semiconductor structure (such as semiconductor structure 100 (FIG. 1), 1400 (FIG. 14), 1500 (FIG. 15), and/or 1600 (FIG. 16)).

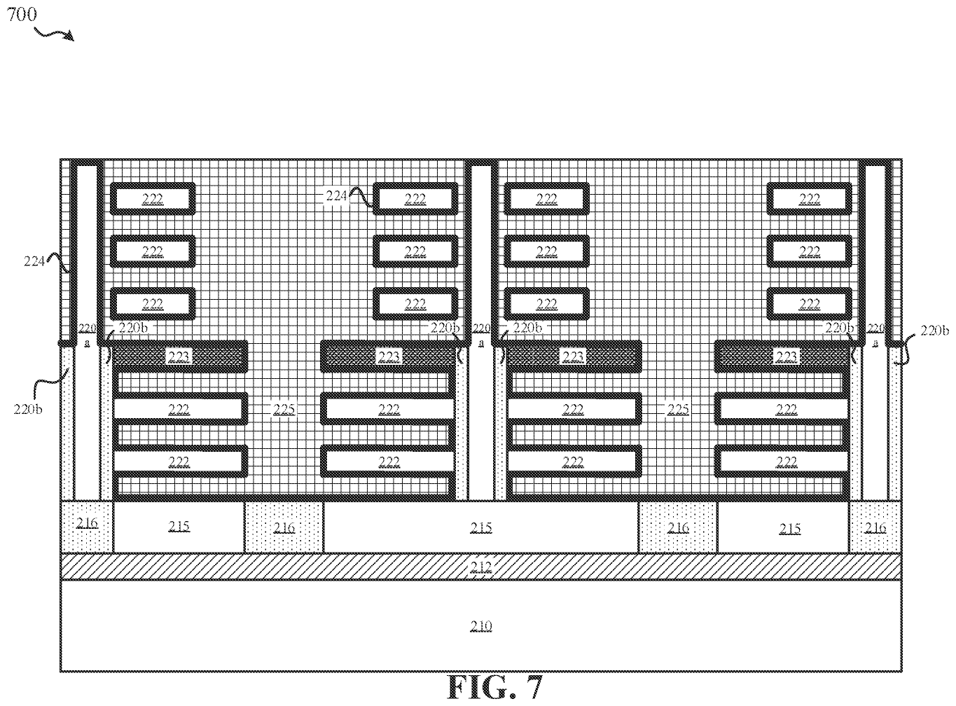

Referring to FIG. 7, a cross-sectional view of an intermediate stage 700 of forming a semiconductor structure is depicted, according to some embodiments. Intermediate stage 700 may include depositing/forming gate(s) 225. Gate(s) 225 may also be referred to herein as replacement metal gate(s) (RMG) 225 as gate(s) 225 are replacing the earlier deposited and removed dummy gate 224 (depicted in FIG. 3). Gate(s) 225 may be deposited through a metal gate fill (for example, a high-k metal gate fill) in order to form metal gate(s) 225. In some instances, gate(s) 225 may be deposited using methods such as ALD, CVD, LCVD, and/or any other deposition technique. In some instances, metal gate(s) 225 may be metal material(s). In some instances, metal gate(s) 225 may contain some combination of gate insulator (such as HfO₂, HfSiOx, HfLaOx, HfAlOx, etc.) and metal material(s), including work function metals (such as TIN, TiAlC, TiC, etc.) and/or conductive metals (such as W, Co, tantalum (Ta), titanium (Ti), niobium (Nb), ruthenium (Ru), etc.).

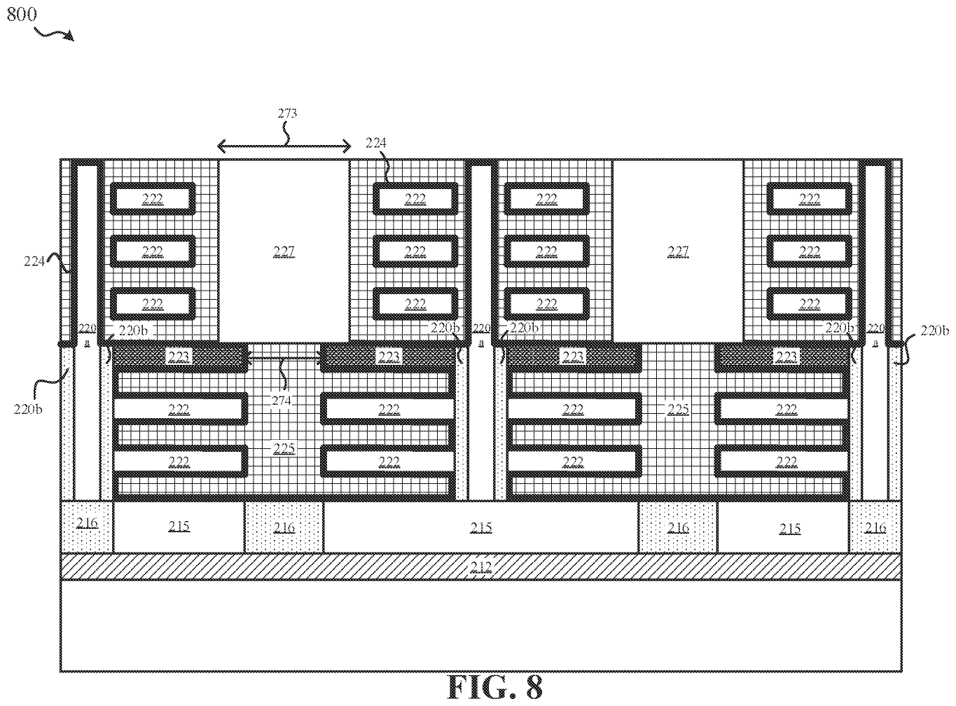

Referring to FIG. 8, a cross-sectional view of an intermediate stage 800 of forming a semiconductor structure is depicted, according to some embodiments. Intermediate stage 800 may include isolating the gate(s) 225 of the top and bottom transistors (i.e., isolating a top portion of gate(s) 225 from a bottom portion of gate(s) 225) through gate cut pillars 227 (also referred to as a CT gate cut). Specifically, intermediate stage 800 may include etching the gate(s) 225 (e.g., through reactive ion etching (RIE), ion beam etching (IBE), and/or any other patterning/etching process) and removing a portion of the gate(s) 225. The opening created by the etching/removing of a portion of the gate(s) 225 may be filled by gate cut pillars 227. In some instances, gate cut pillars 227 may be dielectric material(s) such as SiN, SiO₂, SiBCN, SiOCN, SiC, SiOC, other oxides, etc. In some instances, gate cut pillars 227 may be the same/similar dielectric material(s) as layer 220a of the dielectric bar(s) 220.

In some instances, as discussed herein, gate cut pillars 227 may serve to isolate the top transistor gate(s) 225 from the bottom transistor gate(s) 225. To help isolate the gate(s) 225, gate cut pillars 227 may be directly connected to MDI 223 and may have a width 273 greater than the width 274 between MDIs 223 (also referred to herein as the space 274 between MDIs 223). This helps ensure that there are no points of contact between the top gate(s) 225 and the bottom gate(s) 225.

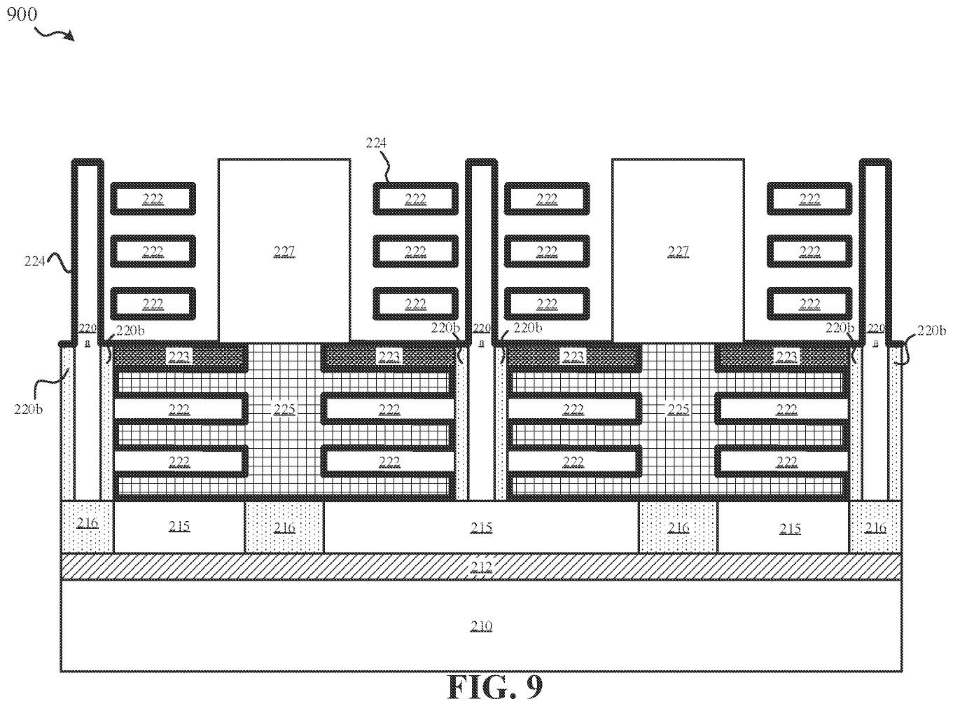

Referring to FIG. 9, a cross-sectional view of an intermediate stage 900 of forming a semiconductor structure is depicted, according to some embodiments. Intermediate stage 900 includes a gate 225 pull (i.e., a pull/removal of a portion of gate(s) 225). Specifically, gate 225 pull may remove a top portion of gate(s) 225 (i.e., the portion of gate(s) 225 corresponding to the top transistor(s) in a set of stacked transistors). The top portion of gate(s) 225 may be the portion(s) of gate(s) 225 above MDIs 223, as discussed herein. In some instances, the gate 225 pull may include removal/etching using a selective wet etch or dry etch process. Gate 225 pull may also be referred to herein as an RMG 225 pull.

In some instances, gate 225 pull may include removing any accessible/exposed portions of the gate(s) 225. These portions of gate(s) 225 may be the portions of gate(s) 225 above MDIs 223 (i.e., the top portions of gate(s) 225). As depicted in FIG. 9, portion/layer 220b may remain in a bottom transistor region (for instance, at/below MDIs 223) of the semiconductor structure of intermediate stage 900. In addition to serving as a dielectric bar 220, layer 220b may also help with the selective gate pull of gate(s) 225. Specifically, layer 220b may serve as another component (for instance, in addition to gate cut pillars 227) to help isolate the bottom gate(s) 225 from any other gates and to block/prevent any selective etching processes from removing any gate(s) in the bottom transistor region (for example, at/below MDIs 223) of the semiconductor structure. For instance, gate cut pillars 227 may block any selective etching pathways to the bottom gate(s) 225 between the nanosheets 222 and/or MDIs 223, and layer 220b of the dielectric bar(s) 220 may block any selective etching pathways to the bottom gate(s) 225 along the dielectric bar(s) 220 and/or between the nanosheets 222/MDIs 223 and the dielectric bar(s) 220. This way, bottom gate(s) 225 are protected from any unwanted etching.

After the gate 225 pull in intermediate stage 900, gate(s) 225 may only remain in a bottom transistor region of the semiconductor structure. Therefore, gate(s) 225 may be referred to hereinafter as bottom gate(s) 225 to help distinguish from other gate(s) that may be formed/deposited herein.

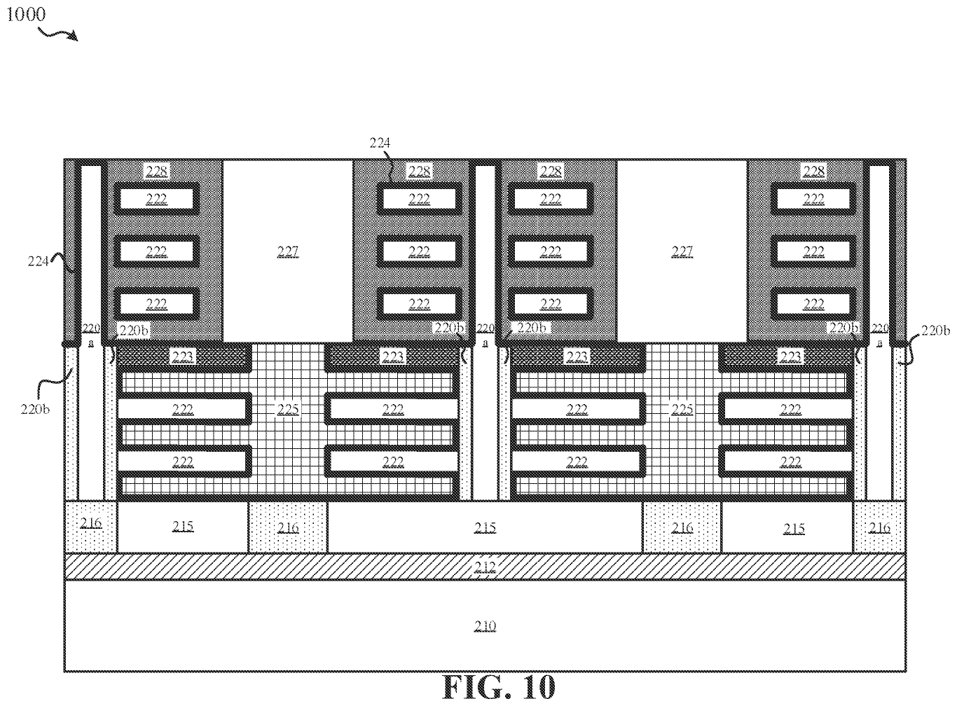

Referring to FIG. 10, a cross-sectional view of an intermediate stage 1000 of forming a semiconductor structure is depicted, according to some embodiments. Intermediate stage 1000 may include depositing/forming top gate(s) 228. Top gate(s) 228 may be referred to as top gate(s) as they are in a top transistor region (i.e., the region of the top transistors in the stacked transistor sets) of the semiconductor structure. Top gate(s) 228 may also be referred to herein as top RMG(s) 228. In some instances, top gate(s) 228 are different material(s) than bottom gate(s) 225. In some instances, top gate(s) are metal material(s) and/or may contain some combination of gate insulator (such as HfO₂, HfSiOx, HfLaOx, HfAlOx, etc.) and metal material(s), including work function metals (such as TIN, TiAlC, TiC, etc.) and/or conductive metals (such as W, Co, tantalum (Ta), titanium (Ti), niobium (Nb), ruthenium (Ru), etc.). Top gate(s) 228 may be deposited through a metal gate fill (for example, a high-k metal gate fill) in order to form metal gate(s) 228. In some instances, gate(s) 228 may be deposited using methods such as ALD, CVD, LCVD, and/or any other deposition technique.

As depicted in FIG. 10, top gate(s) 228 may be a GAA structure, as they may be connected to all sides (for example, four sides when viewing from the cross-section depicted in FIG. 10) of the corresponding nanosheets 222. Bottom gate(s) 225 may be a tri-gate structure, as they may be connected to three sides (when viewing from the cross-section depicted in FIG. 10) of the corresponding nanosheets 222—with the fourth side of the corresponding nanosheets 222 connected to and/or contacting the dielectric bar 220. In some instances, top gate(s) 228 may correspond to gates within a PFET structure and bottom gate(s) 225 may correspond to gates within an NFET structure. Having different gate structures within a stacked transistor set may allow for gates/structures to be better tailored for their specific transistor type. For example, as discussed herein, a PFET may particularly benefit from a GAA structure as a GAA structure may improve hole mobility, whereas an NFET and electron mobility may not be as affected by a number of gates, therefore a tri-gate structure with a dielectric bar 220 may be utilized for an NFET to help improve scaling and decrease spacing between transistors.

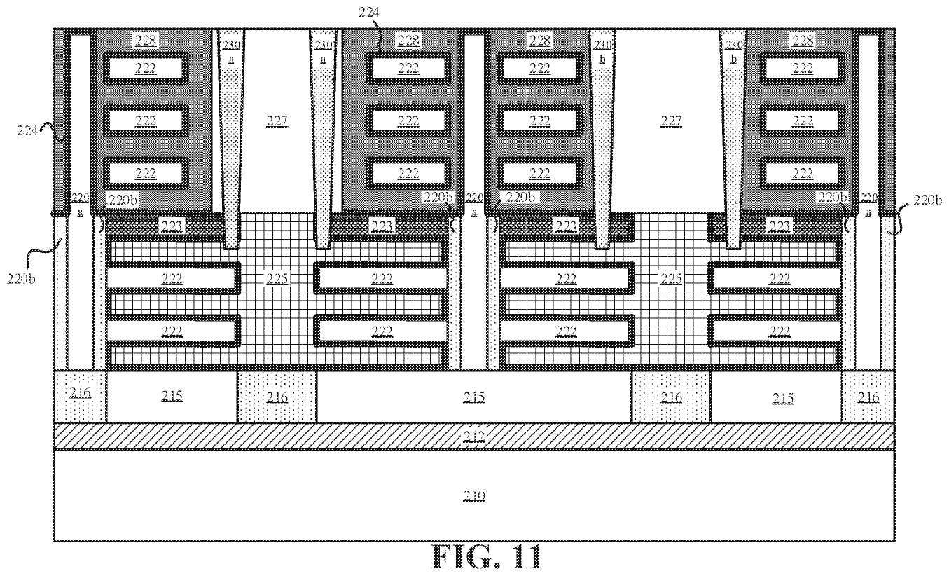

Referring to FIG. 11, a cross-sectional view of an intermediate stage 1100 of forming a semiconductor structure is depicted, according to some embodiments. Intermediate stage 1100 may include forming/creating contact vias 230a and 230b (collectively contact vias 230). Contact vias 230 help connect the bottom gates 225 to other components of the semiconductor structure (discussed further herein). In some instances, as depicted in FIG. 11, the contact vias 230 extend through the MDIs 223 and touch/have direct contact with the bottom gates 225. In some instances, contact vias 230 may be metal contacts, and may be a metal material such as Co, W, Cu, Ru, etc.

FIG. 11 depicts two exemplary types of gate connections, independent gates/connections and dependent gates/connections. For instance, contact vias 230a help form independent gates (between gates 225 and 227) and contact vias 230b help form dependent gates (between gates 225 and 227). Specifically, contact vias 230a are directly connected to the bottom gate 225, however contact vias 230a have no direct connection to top gate(s) 228, and instead contact vias 230a are separated from top gate(s) 228 by gate cut pillar 227. Because contact via 230a has no direct connection to top gate(s) 228, top gate(s) 228 and bottom gate 225 are not connected through contact via 230a, and are independent gates in that region of the semiconductor structure.

For the area of the semiconductor structure with contact vias 230b, contact vias 230b are directly connected to both top gate(s) 228 and bottom gate 225. Therefore, contact via 230b connects top gate(s) 228 and bottom gate 225, resulting in shared gates (225 and 228) in the region with contact vias 230b. Although FIG. 11 depicts an example structure with both independent gates (through contact vias 230a) and shared gates (through contact vias 230b), these structures are meant to be exemplary and not limiting. For example, intermediate stage 1100 may include any combination of independent gates and/or shared gates and their corresponding contact vias.

In some instances, contact vias 230 may be formed by etching openings through the gate cut pillar(s) 227, gate(s) 228, MDI(s) 223, and/or bottom gate(s) 225 and filling the etched openings with metal contact material, thus forming contact vias 230. In some instances, openings for contact vias 230a for an independent gate structure may be etched through the gate cut pillar(s) 227, MDI(s) 223, and bottom gate(s) 225, but not through gate(s) 228. Openings for contact vias 230b for a shared gate structure may be etched through the gate cut pillar(s) 227, gate(s) 228, MDI(s) 223, and bottom gate(s) 225, in some instances.

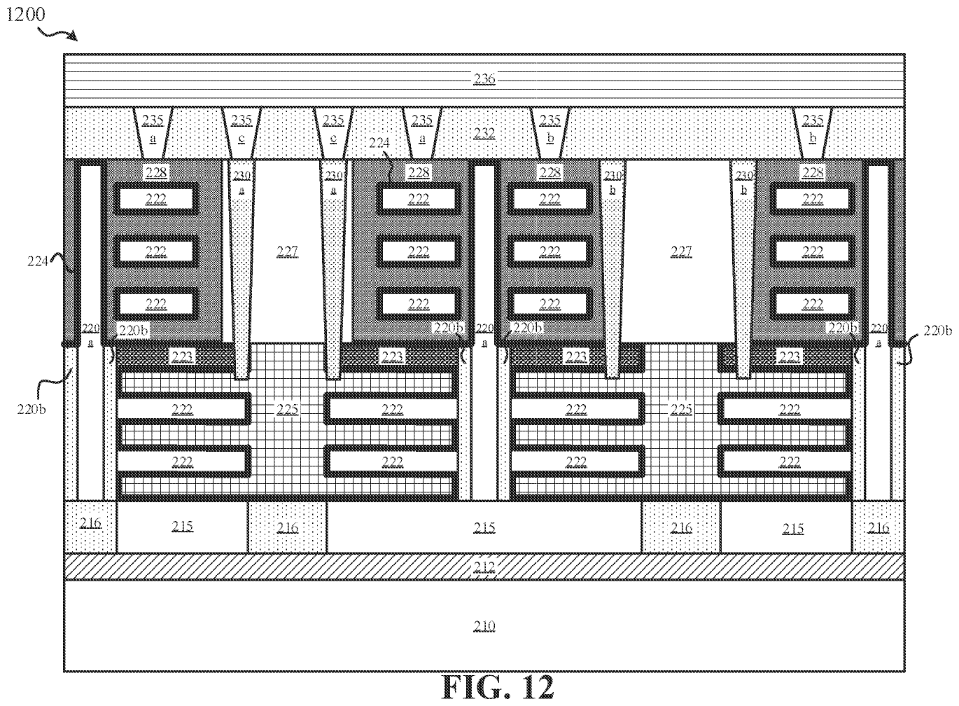

Referring to FIG. 12, a cross-sectional view of an intermediate stage 1200 of forming a semiconductor structure is depicted, according to some embodiments. Intermediate stage 1200 may include forming frontside contacts 235a, 235b, and 235c (referred to collectively as frontside contacts 235) and depositing dielectric 232 to help protect and prevent any unwanted current/heat transfer to and/or from the frontside contacts 235. In some instances, frontside contacts 235 are middle of line (MOL) contacts.

As discussed herein, contact vias 230a may create independent gates (225 and 228) and contact vias 230b may create shared gates (225 and 228). In a shared gate structure, only frontside contacts 235b directly connected to top gates 228 may be needed to connect the gates (225 and 228) to the frontside interconnect 236, as bottom gates 225 may be connected to frontside contacts 235b and frontside interconnect 236 through contact vias 230b and gates 228. Put differently, the shared gate connection between gates 225 and 228 created by contact vias 230b may be utilized to help connect gate(s) 225 to frontside interconnect 236.

In an independent gate structure, such as the independent gate structure created by contact vias 230a, more frontside contacts (for example, frontside contacts 235a and 235c) may be needed. For instance, separate frontside contacts (235a and 235c) may connect the bottom gate(s) 225 to the frontside interconnect 236 and the top gates 228 to the frontside interconnect. In intermediate stage 1200, contact vias 230a and frontside contacts 235c connect the bottom gate(s) 225 to the frontside interconnect 236. Frontside contacts 235a connect the top gates 228 to the frontside interconnect 236 (as there is no shared connection between gate(s) 225 and 228 through contact vias 230a).

Although FIG. 12 depicts an example intermediate stage 1200 with separate frontside contacts 235a and 235c for an independent gate structure, and shared frontside contacts 235b for a shared gate structure, this is meant to be exemplary and not limiting. For example, intermediate stage 1200 may include only shared gate structures, shared contact vias 230b, and shared frontside contacts 235b; only independent gate structures, independent contact vias 230a, and independent frontside contacts 235a and 235c; and/or any combination of shared and independent gate structures, contact vias, and frontside contacts.

In some instances, intermediate stage 1200 further includes forming/depositing frontside interconnect 236. In some instances, frontside interconnect 236 is a back end of line (BEOL) interconnect.

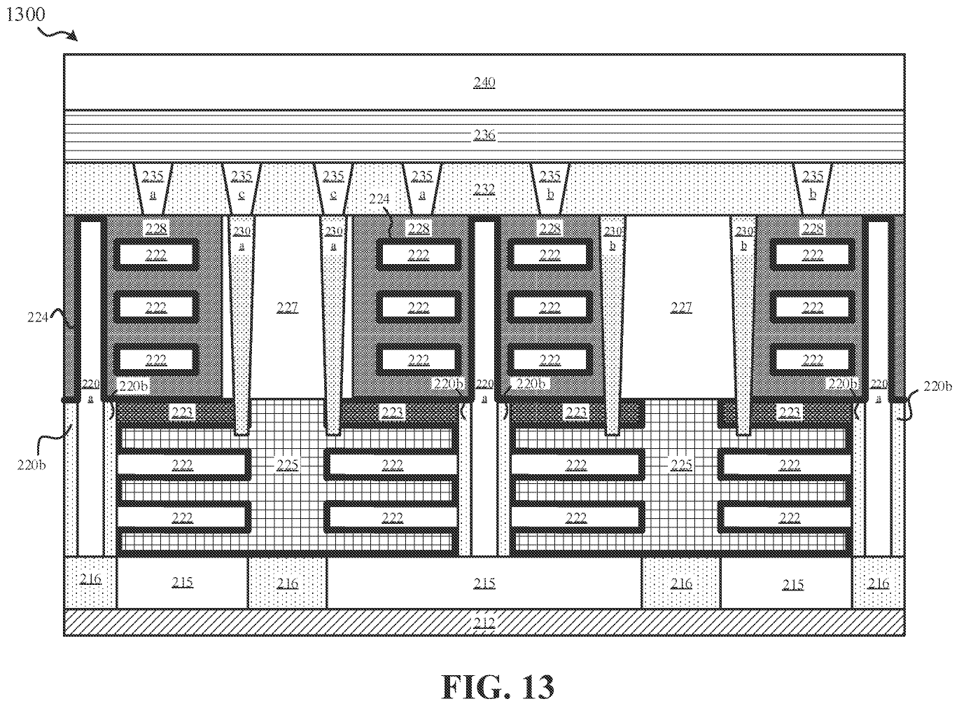

Referring to FIG. 13, a cross-sectional view of an intermediate stage 1300 of forming a semiconductor structure is depicted, according to some embodiments. Intermediate stage 1300 may include bonding frontside interconnect 236 to wafer 240 (for example, a handler wafer). Intermediate stage 1300 may also include removing substrate 210. In some instances, removing substrate 210 may include etching/removing up to etch stop layer 212. In some instances, substrate 210 may be removed through grinding, chemical mechanical planarization (CMP), RIE, IBE, wet etch, and/or any other removal/etching process. Etch stop layer 212 may help protect other components of intermediate stage 1300 from any unwanted etching.

In some instances, although substrate 210 and wafer/substrate 215 are depicted as separate entities, substrates 210 and 215 may be a part of the same substrate/wafer, and may be referred to as a wafer and/or substrate 210, 215. Therefore, the removal of substrate 210 may be considered a thinning/reduction of the wafer/substrate 210, 215 and may also be referred to as a back-side wafer (or substrate) 210, 215 thinning.

Referring to FIG. 14, a cross-sectional view of an example semiconductor structure 1400 is depicted, according to some embodiments. Semiconductor structure 1400 (and some of its components) may correspond to semiconductor structure 100 (FIG. 1) in some instances.

In some instances, to finish forming semiconductor structure 1400 (i.e., to transition from intermediate stage 1300 (FIG. 13) to semiconductor structure 1400), etch stop layer 212 may be removed, backside contacts 250 may be formed (for example, through a backside gate cut (BSCT)), and backside interconnect 245 may be deposited/formed.

In some instances, as depicted in FIG. 14, backside contacts 250 may connect backside interconnect 245 to bottom gates 225. For instance, backside contacts 250 may be directly connected to backside interconnect 245 and gates 225. In some instances, backside contacts may also be in direct contact with gate cut pillars 227, but may not have any direct contact with top gates 228.

As depicted in FIG. 14, semiconductor structure 1400 depicts a plurality of sets of stacked transistors with top transistors 262 and bottom transistors 264. The top transistors 262 may be nanosheet 222 transistors with a gate-all-around (GAA) structure, as the top gates 228 go all around (i.e., around each of the four sides) of the nanosheets 222. This may be especially beneficial for PFETs and hole mobility. The set(s) of stacked transistors may also include a dielectric bar 220 to help improve scaling and reduce spacing between transistors. The bottom transistors 264 may be nanosheet 222 transistors with a tri-gate structure and a dielectric bar 222, as the bottom gates 225 are in contact with three of the sides of the nanosheets 222 and the dielectric bar 222 is in contact with the fourth side of the nanosheets 222. The tri-gate structure and dielectric bar 222 combination of the bottom transistors 264 may be referred to herein as a dielectric bar transistor and/or a forksheet transistor, as the channels/nanosheets 222 are in direct contact with the dielectric bar 220 and are surrounded on the remaining three sides by bottom gate(s) 225.

Stacked transistors (i.e., top transistors 262 and bottom transistors 264) with different structures and gate configurations for each of the top 262 and bottom 264 transistors may help improve the functionality of the stacked transistors, as the structures and gate configurations may be tailored to the specific transistor types. For instance, as discussed herein, while dielectric bars are very beneficial for scaling/reducing the size of the semiconductor structure 1400, PFETs may struggle with a tri-gate structure of a conventional dielectric bar/forksheet structure, due to the negative effects to hole mobility. A GAA structure, such as gates 228, for PFETs may improve the functionality and hole mobility of the PFETs. Therefore, semiconductor structure 1400 is able to achieve the scaling benefits by utilizing a dielectric bar 220 while also maintaining/improving hole mobility of the top transistors 262 due to the GAA structure of gates 228.

Although FIG. 14 depicts a semiconductor structure 1400 with four sets of stacked transistors, semiconductor structure 1400 may include any number of stacked transistors/stacked transistor structures.

Referring to FIG. 15, a cross-sectional view of an example semiconductor structure 1500 is depicted, according to some embodiments. FIG. 15 depicts an example semiconductor structure, semiconductor structure 1500, with contacts 1535 having a back-side connection to the bottom gates 225. Put differently, in an independent gate structure (where gates 228 and 225 are fully independent/separate from each other), there are instances where the bottom gates 225 have a backside connection to backside interconnect 245 through at least contacts 1535. In some instances, as depicted in FIG. 14, bottom gates 225 may have a connection to frontside interconnect 236 through contact vias 230 and contacts 235. In instances where bottom gates 225 are not connected to frontside interconnect 236 (as depicted in FIG. 15), contact vias 230 (FIG. 14) may not be useful (as there is no use for a connection between bottom gates 225 and frontside interconnect 236 in these instances).

Referring to FIG. 16, a cross-sectional view of an example semiconductor structure 1600 is depicted, according to some embodiments. FIG. 16 depicts an example semiconductor structure 1600 with frontside integration only (no backside integration). In this example, both the top gates 228 and the bottom gates 225 may be connected to (i.e., have a front-side connection to) frontside interconnect 236. Contacts 1650 may be frontside contacts to help connect bottom gates 225 to frontside interconnect 236. In instances where there is no backside integration and no backside interconnect 245 (FIG. 14) as depicted in FIG. 16, backside contacts 250 (FIG. 14) may not be needed to connect components to the backside interconnect 245 (FIG. 14). In some instances, semiconductor structure 1600 includes an extended wafer/substrate. The extended portion of the wafer/substrate is depicted as extension 1615, and the entire wafer/substrate may include both 215 and 1615, resulting in wafer/substrate 215, 1615, in some instances.

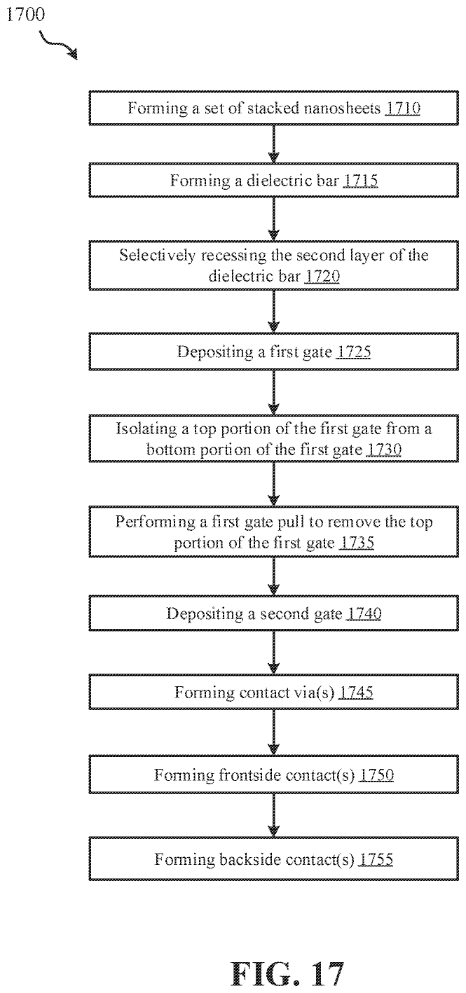

Referring now to FIG. 17, a flowchart of an example method 1700 of forming a semiconductor structure (for example, semiconductor structure 100 (FIG. 1), semiconductor structure 1400 (FIG. 14), semiconductor structure 1500 (FIG. 15), and/or semiconductor structure 1600 (FIG. 16)) is depicted, according to some embodiments. In some instances, method 1700 may correspond to intermediate stages 200-1300 (FIGS. 2-13).

Method 1700 includes operation 1710 of forming a set of stacked nanosheets. This may correspond to FIG. 2, in some instances. In some instances, the set of stacked nanosheets include top nanosheets and bottom nanosheets. Top nanosheets and bottom nanosheets may each include one or more nanosheets, in some instances. As discussed herein (for example, in relation to FIG. 2), the width of the bottom nanosheets may be greater/wider than the width of the top nanosheets, in some instances. In some instances, as depicted in FIG. 2, the set of stacked nanosheets (e.g., nanosheets 222 (FIG. 2)) may be formed/deposited with sacrificial sheets (e.g., sacrificial sheets 221 (FIG. 2)) separating each nanosheet in the stack. In some instances, there may be a middle dielectric isolation (MDI) layer (e.g., MDI 223 (FIG. 2)) deposited between the top nanosheets and the bottom nanosheets to help separate the top nanosheets and the top transistor from the bottom nanosheets and the bottom transistor.

Method 1700 includes operation 1715 of forming a dielectric bar. This may correspond to FIG. 2 in some instances. In some instances, as depicted in FIG. 2, the dielectric bar (e.g., dielectric bar 220 (FIG. 2)) may include a first layer (e.g., layer 220a (FIG. 2)) and a second layer (e.g., layer 220b (FIG. 2)). The second layer may be directly connected to the set of stacked nanosheets (as depicted in FIG. 2).

Method 1700 includes operation 1720 of selectively recessing the second layer of the dielectric bar. This may correspond to FIG. 5 and intermediate stage 500, in some instances. In some instances, the selective recessing of the second layer may result in a space between the top nanosheets and the dielectric bar. As discussed herein, it may be beneficial to have stacked transistors with different gate structures for the top and bottom transistors. Specifically, it may be beneficial to have a GAA structure, or a GAA transistor, for a PFET to help with hole mobility. To achieve a GAA structure for the top transistor, which in some instances may be a PFET, a portion of the second layer (e.g., layer 220b (FIG. 5)) may be selectively recessed in order to create space between the top nanosheets and the dielectric bar. In some instances, the second layer may be recessed to a middle of an MDI layer (such as MDI 223 (FIG. 5)). The MDI may help separate the top transistor from the bottom transistor, therefore selectively recessing the second layer to the middle of the MDI may create the space between the top nanosheets and the dielectric bar without creating any space below the MDI (for example, between the bottom nanosheets and the dielectric bar). This created space may later be filled by gate material to help form/achieve a GAA structure for the top transistor and top nanosheets. In some instances, the second layer of the dielectric bar may be selectively recessed using RIE.

Method 1700 includes operation 1725 of depositing a first gate. This may correspond to FIG. 7 and intermediate stage 700, in some instances. In some instances, the first gate may correspond to gate(s) 125 (FIG. 1) and/or gate(s) 225 (FIGS. 7-16). In some instances, as depicted in FIG. 7, the first gate (e.g., gate(s) 225) may be deposited in both the top and bottom transistor regions of a semiconductor structure, and may be connected to both the top nanosheets and bottom nanosheets. In some instances, while the first gate may be connected to the top and bottom nanosheets, a thin layer of inter-layer/high-k dielectric (IL/HK dielectric) (such as IL/HK dielectric 224 (FIG. 7)) may be between the nanosheets and the first gate.

Method 1700 includes operation 1730 of isolating a top portion of the first gate from a bottom portion of the first gate. This may correspond to FIG. 8 and intermediate stage 800, in some instances. In some instances, isolating a top portion of the first gate from a bottom portion of the first gate may include forming one or more gate cut pillars (e.g., gate cut pillar(s) 227 (FIG. 8)).

Method 1700 includes operation 1735 of performing a first gate pull to remove the top portion of the first gate. This may correspond to FIG. 9 and intermediate stage 900, in some instances. In some instances, the first gate pull may remove a portion of the first gate (i.e., the top portion) in a top transistor region of the semiconductor structure.

Method 1700 includes operation 1740 of depositing a second gate. Operation 1740 may correspond to FIG. 10 and intermediate stage 1000, in some instances. In some instances, the second gate may correspond to gate(s) 128 (FIG. 1) and/or gate(s) 228 (FIGS. 10-16). In some instances, as discussed herein, the second gate, or top gate, may be different material(s) than the first gate, or bottom gate.

In some instances, as depicted in FIG. 17, method 1700 includes operation 1745 of forming contact via(s). This may correspond to intermediate stage 1100 and FIG. 11, in some instances. In some instances, as discussed herein, the contact via(s) may help create independent gate structures and/or shared gate structures. For example, as discussed herein, contact via(s) 230a (FIG. 11) may create an independent gate structure between the first gate (e.g., gate 225) and the second gate (e.g., gate 228). Contact via(s) 230b (FIG. 11) may create a shared gate structure between the first gate (e.g., gate 225) and the second gate (e.g., gate 228).

In some instances, as depicted in FIG. 17, method 1700 may include operation 1750 of forming frontside contact(s). This may correspond to FIG. 12 and intermediate stage 1200, in some instances. As discussed herein and depicted in FIGS. 12-16, one or more of the gates (e.g., first gate(s) (e.g., gate(s) 225) and/or second gate(s) (e.g., gate 228)) may be connected to a frontside interconnect through frontside contacts (such as frontside contacts 235a, 235b, and/or 235c).

In some instances, as depicted in FIG. 17, method 1700 may include operation 1755 of forming backside contact(s). This may correspond to FIG. 14 in some instances. As discussed herein and depicted in FIGS. 12-15, there are instances where one or more of the gates (e.g., first gate(s) (e.g., gate(s) 225) and/or second gate(s) (e.g., gate 228)) may be connected to a backside interconnect through various contacts (such as contacts 250, contacts 1535, etc.). However, in some instances (as depicted in FIG. 16 and discussed herein), there may be instances where the first gate(s) and second gate(s) are only connected to a frontside interconnect and are not connected to a backside interconnect. In these instances, backside contacts may not be formed and method 1700 may not include operation 1755.

In some instances, method 1700 may include additional steps not depicted in FIG. 17. For example, method 1700 may include any of the intermediate stages (e.g., 200-1300 (FIGS. 2-13)) discussed herein in relation to forming semiconductor structure 1400 (FIG. 14), semiconductor structure 1500 (FIG. 15), semiconductor structure 1600 (FIG. 16), and/or semiconductor structure 100 (FIG. 1).

The present invention may be a system, a method, a computer program product, etc. at any possible technical detail level of integration.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to some embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, wherein the semiconductor structure comprises:
a set of stacked transistors, wherein the set of stacked transistors comprises:
a first transistor, wherein the first transistor comprises a first gate having a gate-all-around (GAA) structure;
a second transistor, wherein the second transistor has a gate structure different than a GAA structure; and
a dielectric bar.

2. The semiconductor structure of claim 1, wherein the second transistor comprises a second gate having a tri-gate structure.

3. The semiconductor structure of claim 1, wherein the first transistor is in a top region of the set of stacked transistors and the second transistor is in a bottom region of the set of stacked transistors.

4. The semiconductor structure of claim 3, wherein the dielectric bar has a first width in the top region of the set of stacked transistors and a second width, different from the first width, in the bottom region of the set of stacked transistors.

5. The semiconductor structure of claim 4, wherein the second width is wider than the first width.

6. The semiconductor structure of claim 3, wherein the dielectric bar comprises a first layer and a second layer.

7. The semiconductor structure of claim 6, wherein the first layer is in the top region and the bottom region and wherein the second layer is only in the bottom region.

8. The semiconductor structure of claim 6, wherein the second layer comprises one or more different materials than the first layer.

9. The semiconductor structure of claim 3, wherein the first transistor has a first gate extension between one or more channels and the dielectric bar and a second gate extension, different from the first gate extension, between the one or more channels and a gate cut pillar.

10. The semiconductor structure of claim 9, wherein the first gate extension is smaller than the second gate extension.

11. The semiconductor structure of claim 9, wherein the one or more channels are nanosheets.

12. A system, wherein the system comprises:
a semiconductor structure, wherein the semiconductor structure comprises:
a set of stacked transistors, wherein the set of stacked transistors comprises:
a first transistor, wherein the first transistor comprises a first one or more channels and a first gate having a gate-all-around (GAA) structure;
a second transistor, wherein the second transistor comprises a second one or more channels and a second gate, the second transistor having a gate structure different than a GAA structure; and
a dielectric bar.

13. The system of claim 12, wherein the second gate has a tri-gate structure.

14. The system of claim 12, wherein the first one or more channels have a first width and the second one or more channels have a second width different than the first width.

15. The system of claim 14, wherein the second width is greater than the first width.

16. The system of claim 12, further comprising:
a contact via connected to the first gate and the second gate; and
a contact connected to the first gate and an interconnect, wherein the second gate is connected to the interconnect through the contact via and the first gate.

17. The system of claim 12, further comprising:
a contact via connected to the second gate, wherein the contact via is separated from the first gate;
a first contact connected to the contact via and an interconnect, wherein the second gate is connected to the interconnect through the contact via and the first contact; and
a second contact connected to the first gate and the interconnect.

18. The system of claim 12, wherein the dielectric bar has a first width in a top region of the set of stacked transistors and a second width, different from the first width, in a bottom region of the set of stacked transistors.

19. The system of claim 18, wherein the second width is wider than the first width.

20. A method of forming a semiconductor structure, the method comprising:
forming a set of stacked nanosheets, the set of stacked nanosheets comprising top nanosheets and bottom nanosheets;
forming a dielectric bar, the dielectric bar comprising a first layer and a second layer, wherein the second layer is directly contacting the set of stacked nanosheets;
selectively recessing the second layer of the dielectric bar, resulting in a space between the top nanosheets and the dielectric bar;
depositing a first gate; and
depositing a second gate, wherein the second gate surrounds all sides of the top nanosheets, resulting in a gate-all-around (GAA) structure for the second gate.
